(19) United States
(12) Patent Application Publication
(10) Pub. No.: US 2023/0097621 A1
(43) Pub. Date: Mar. 30, 2023

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Hiroto IGAWA, Toyama (JP); Masanori NAKAYAMA, Toyama (JP); Katsunori FUNAKI, Toyama (JP); Tatsushi UEDA, Toyama (JP); Yasutoshi TSUBOTA, Toyama (JP); Yuichiro TAKESHIMA, Toyama (JP); Keita ICHIMURA, Toyama (JP); Yuki YAMAKADO, Toyama (JP); Hiroki KISHIMOTO, Toyama (JP)

(73) Assignee: KOKUSAI ELECTRIC CORPORATION, Tokyo (JP)

(21) Appl. No.: 17/945,891

(22) Filed: Sep. 15, 2022

(30) Foreign Application Priority Data
Sep. 30, 2021 (JP) 2021-161015

(51) Int. Cl. H01L 21/02; H01J 37/32; C23C 8/12; C23C 8/36

(52) U.S. Cl. CPC H01L 21/02252; H01L 21/02164; H01L 21/02238; H01J 37/3244; C23C 8/12; C23C 8/36; H01J 2237/338

(57) ABSTRACT

A method of processing a substrate, includes: (a) modifying a surface of the substrate into a first oxide layer by supplying, to the substrate, a reactive species generated by plasma-exciting a first processing gas in which oxygen and hydrogen are contained and a ratio of hydrogen in the oxygen and hydrogen of the first processing gas is a first ratio; and (b) modifying the first oxide layer into a second oxide layer by supplying, to the substrate, a reactive species generated by plasma-exciting a second processing gas in which oxygen is contained and hydrogen is optionally contained and a ratio of hydrogen in the oxygen and hydrogen of the second processing gas is a second ratio smaller than the first ratio.

### CROSS-REFERENCE TO RELATED APPLICATION

This application is based upon and claims the benefit of priority from Japanese Patent Application No. 2021-161015, filed on Sep. 30, 2021, the entire contents of which are incorporated herein by reference.

### TECHNICAL FIELD

The present disclosure relates to a method of processing a substrate, a method of manufacturing a semiconductor device, a substrate processing apparatus, and a recording medium.

### BACKGROUND

As a process of manufacturing a semiconductor device, a process of modifying a surface of a film formed on a substrate into an oxide layer by using a gas excited by plasma may be performed.

### SUMMARY

Some embodiments of the present disclosure provide a technique capable of modifying a surface of a substrate into an oxide layer having a desired thickness and excellent properties even under low temperature conditions.

According to embodiments of the present disclosure, a method of processing a substrate, includes: (a) modifying a surface of the substrate into a first oxide layer by supplying, to the substrate, a reactive species generated by plasma-exciting a first processing gas in which oxygen and hydrogen are contained and a ratio of hydrogen in the oxygen and hydrogen of the first processing gas is a first ratio; and (b) modifying the first oxide layer into a second oxide layer by supplying, to the substrate, a reactive species generated by plasma-exciting a second processing gas in which oxygen is contained and hydrogen is optionally contained and a ratio of hydrogen in the oxygen and hydrogen of the second processing gas is a second ratio smaller than the first ratio.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a substrate processing apparatus 100 suitably used in some embodiments of the present disclosure, in which a portion of a process furnace 202 is illustrated in a vertical sectional view.

FIG. 2 is an explanatory diagram for explaining a plasma generation principle in the substrate processing apparatus 100 suitably used in some embodiments of the present disclosure.

FIG. 3 is a schematic configuration diagram of a controller 221 included in the substrate processing apparatus 100 suitably used in some embodiments of the present disclosure, in which a control system of the controller 221 is illustrated in a block diagram.

FIG. 4 is a diagram showing a relationship between a percentage of hydrogen in the oxygen and hydrogen contained in a processing gas and a thickness of an oxide layer formed by a modification process for each processing temperature.

FIG. 5 is a diagram showing a relationship between a processing temperature and a thickness of an oxide layer formed by a modification process for each ratio value of hydrogen in the oxygen and hydrogen contained in a processing gas.

FIG. 6 is a schematic configuration diagram of a substrate processing apparatus 100′ suitably used in some embodiments of the present disclosure, in which a portion of a process furnace 202 is illustrated in a vertical sectional view.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

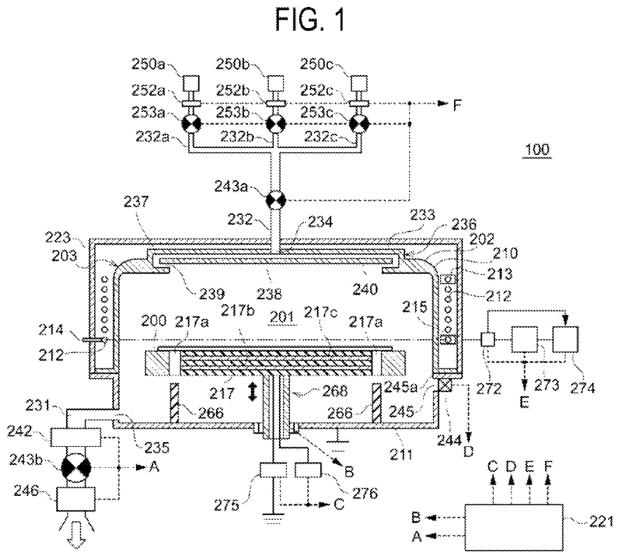

Hereinafter, some embodiments of the present disclosure will be described mainly with reference to FIGS. 1 to 5. The drawings used in the following description are all schematic. The dimensional relationship of each element on the drawings, the ratio of each element, and the like do not always match the actual ones. Further, even between the drawings, the dimensional relationship of each element, the ratio of each element, and the like do not always match.

### (1) Configuration of Substrate Processing Apparatus

As shown in FIG. 1, the substrate processing apparatus 100 includes a process furnace 202 configured to accommodate a wafer 200 as a substrate and perform plasma processing. The process furnace 202 includes a process container 203 that constitutes a process chamber 201. The process container 203 includes a dome-shaped upper container 210 as a first container and a bowl-shaped lower container 211 as a second container. The process chamber 201 is formed by covering the lower container 211 with the upper container 210. The upper container 210 is made of a nonmetallic material such as aluminum oxide (Al₂O₃) or quartz (SiO₂), and the lower container 211 is made of, for example, aluminum (Al).

A gate valve 244 as a loading/unloading valve (partition valve) is installed on the lower sidewall of the lower container 211. By opening the gate valve 244, the wafer 200 can be loaded and unloaded into and from the process chamber 201 through a loading/unloading port 245. By closing the gate valve 244, the airtightness in the process chamber 201 can be maintained.

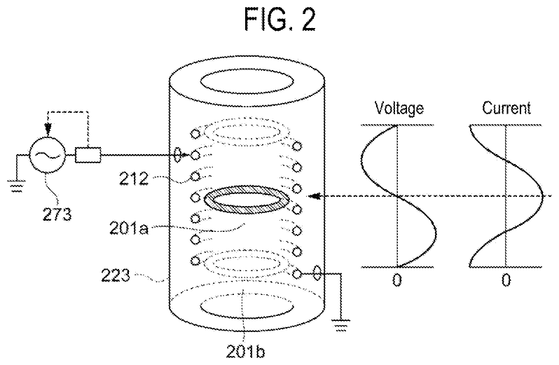

As shown in FIG. 2, the process chamber 201 includes a plasma generation space 201a and a substrate processing space 201b which communicates with the plasma generation space 201a and in which the wafer 200 is processed. The plasma generation space 201a is a space in which plasma is generated, and refers to, for example, a space existing above the lower end of a resonance coil 212 (one-dot chain line in FIG. 1) in the process chamber 201. On the other hand, the substrate processing space 201b is a space in which the wafer 200 is processed with plasma, and refers to a space existing below the lower end of the resonance coil 212.

A susceptor 217 as a substrate mounting part on which the wafer 200 is mounted is arranged at the bottom-side center of the process chamber 201. The susceptor 217 is made of a nonmetallic material such as aluminum nitride (AlN), ceramics, quartz, or the like.

A heater 217b as a heating mechanism is integrally embedded in the susceptor 217. By supplying electric power to the heater 217b through a heater power adjustment mechanism 276, the surface of the wafer 200 can be heated to a predetermined temperature within a range of, for example, 25 degrees C. to 1000 degrees C.

The susceptor 217 is electrically insulated from the lower container 211. An impedance adjustment electrode 217c is installed inside the susceptor 217. The impedance adjustment electrode 217c is grounded through an impedance changing mechanism 275 as an impedance adjustment part. The impedance changing mechanism 275 includes a coil, a variable capacitor, or the like. By controlling the inductance and resistance of the coil, the capacitance value of the variable capacitor, and the like, the impedance changing mechanism 275 can change the impedance of the impedance adjustment electrode 217c in the range from about 0Ω to the parasitic impedance of the process chamber 201. This makes it possible to control the potential (bias voltage) of the wafer 200 during plasma processing via the impedance adjustment electrode 217c and the susceptor 217.

A susceptor elevating mechanism 268 for elevating the susceptor is installed below the susceptor 217. Through-holds 217a are installed in the susceptor 217. Support pins 266 as supports for supporting the wafer 200 is installed on the bottom surface of the lower container 211. At least three through-holes 217a and at least three support pins 266 are installed at positions facing each other. When the susceptor 217 is lowered by the susceptor elevating mechanism 268, the support pins 266 protrude through the through-holes 217a without contacting the susceptor 217. As a result, it is possible to hold the wafer 200 from below.

A gas supply head 236 is installed above the process chamber 201, that is, above the upper container 210. The gas supply head 236 includes a cap-shaped lid 233, a gas introduction port 234, a buffer chamber 237, an opening 238, a shielding plate 240, and a gas discharge port 239. The gas supply head 236 is configured to supply a gas into the process chamber 201. The buffer chamber 237 functions as a dispersion space for dispersing a reaction gas introduced from the gas introduction port 234.

A downstream end of a gas supply pipe 232a for supplying a hydrogen-containing gas containing hydrogen (H), a downstream end of a gas supply pipe 232b for supplying an oxygen-containing gas containing oxygen (O), and a downstream end of a gas supply pipe 232c for supplying an inert gas are connected to the gas introduction port 234 so as to join to each other. On the gas supply pipe 232a, a hydrogen-containing gas supply source 250a, a mass flow controller (MFC) 252a as a flow rate control device, and a valve 253a as an on-off valve are installed sequentially from the upstream side. On the gas supply pipe 232b, an oxygen-containing gas supply source 250b, an MFC 252b as a flow rate control device, and a valve 253b as an on-off valve are installed sequentially from the upstream side. On the gas supply pipe 232c, an inert gas supply source 250c, an MFC 252c as a flow rate control device, and a valve 253c as an on-off valve are installed sequentially from the upstream side. A valve 243a is installed on the downstream side of a location where the gas supply pipe 232a, the gas supply pipe 232b, and the gas supply pipe 232c join to each other. The valve 243a is connected to the upstream end of the gas introduction port 234. By opening and closing the valves 253a to 253c and 243a, a hydrogen-containing gas, an oxygen-containing gas, and an inert gas can be supplied into the process chamber 201 through the gas supply pipes 232a, 232b and 232c while adjusting the flow rates of the respective gases with the MFCs 252a to 252c.

A hydrogen-containing gas supply system is mainly configured by the gas supply head 236 (the lid 233, the gas introduction port 234, the buffer chamber 237, the opening 238, the shielding plate 240, and the gas discharge port 239), the gas supply pipe 232a, the MFC 252a, and the valves 253a and 243a. An oxygen-containing gas supply system is mainly configured by the gas supply head 236, the gas supply pipe 232b, the MFC 252b, and the valves 253b and 243a. An inert gas supply system is mainly configured by the gas supply head 236, the gas supply pipe 232c, the MFC 252c, and the valves 253c and 243a.

An exhaust port 235 for exhausting the inside of the process chamber 201 is installed in a sidewall of the lower container 211. An upstream end of an exhaust pipe 231 is connected to the exhaust port 235. On the exhaust pipe 231, an APC (Auto Pressure Controller) valve 242 as a pressure regulator (pressure regulation part), a valve 243b, and a vacuum pump 246 as an evacuation device are installed sequentially from the upstream side.

An exhaust part is mainly configured by the exhaust port 235, the exhaust pipe 231, the APC valve 242, and the valve 243b. The vacuum pump 246 may be included in the exhaust part.

A spiral resonance coil 212 is installed on the outer periphery of the process chamber 201, that is, on the outside of the sidewall of the upper container 210 so as to surround the process chamber 201. An RF (Radio Frequency) sensor 272, a high-frequency power source 273, and a frequency matcher 274 (frequency control part) are connected to the resonance coil 212. A shield plate 223 is installed on the outer peripheral side of the resonance coil 212.

The high-frequency power source 273 is configured to supply high-frequency power to the resonance coil 212. The RF sensor 272 is installed on the output side of the high-frequency power source 273. The RF sensor 272 is configured to monitor information on a traveling wave and a reflected wave of the high-frequency power supplied from the high-frequency power source 273. The frequency matcher 274 is configured to match the frequency of the high-frequency power outputted from the high-frequency power source 273 based on the reflected wave power information monitored by the RF sensor 272 so as to minimize the reflected wave.

Both ends of the resonance coil 212 are electrically grounded. One end of the resonance coil 212 is grounded through a movable tap 213. The other end of the resonance coil 212 is grounded through a fixed ground 214. A movable tap 215 is installed between these ends of the resonance coil 212 so as to arbitrarily set the position at which electric power is supplied from the high-frequency power source 273.

An excitation part (plasma generator) for exciting the gases supplied into the process chamber 201 (the plasma generation space 201a), such as the gases supplied from the hydrogen-containing gas supply system and the oxygen-containing gas supply system is mainly configured by the resonance coil 212, the RF sensor 272, and the frequency matcher 274. The high-frequency power source 273 and the shielding plate 223 may be included in the excitation part.

The operation of the excitation part and the properties of the generated plasma will be supplemented with reference to FIG. 2.

The resonance coil 212 is configured to function as a high-frequency inductively coupled plasma (ICP) electrode. The resonance coil 212 forms a standing wave of a predetermined wavelength, and the winding diameter, winding pitch, number of windings, etc. of the resonance coil 212 are set so that the resonance coil 212 can resonate in a full wavelength mode. The electrical length of the resonance coil 212, that is, the electrode length between the grounds is adjusted so as to be an integral multiple of the wavelength of the high-frequency power supplied from the high-frequency power source 273. These configurations, the electric power supplied to the resonance coil 212, the intensity of the magnetic field generated by the resonance coil 212, and the like are appropriately determined in consideration of the external shape of the substrate processing apparatus 100, the processing contents, and the like. As an example, the resonance coil 212 has a coil diameter of 200 to 500 mm and a coil winding number of 2 to 60.

The high-frequency power source 273 includes a power controller and an amplifier. The power controller is configured to output a predetermined high-frequency signal (control signal) to the amplifier based on output conditions related to the power and frequency which are preset through an operation panel. The amplifier is configured to output a high-frequency power obtained by amplifying a control signal received from the power controller toward the resonance coil 212 via a transmission line.

The frequency matcher 274 receives a voltage signal related to the reflected wave power from the RF sensor 272, and performs correction control to increase or decrease the frequency (oscillation frequency) of the high-frequency power outputted by the high-frequency power source 273 so that the reflected wave power can be minimized.

With the configuration described above, the inductive plasma excited in the plasma generation space 201a has a good quality with little capacitive coupling with the inner wall of the process chamber 201, the susceptor 217, and the like. In the plasma generation space 201a, the plasma having an extremely low electrical potential and having a doughnut shape in a plan view is generated.

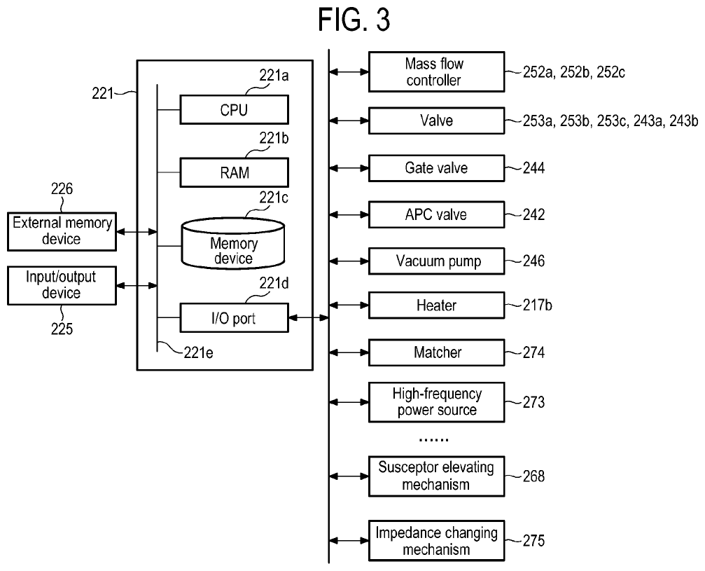

As shown in FIG. 3, the controller 221 as a control part is configured as a computer that includes a CPU (Central Processing Unit) 221a, a RAM (Random Access Memory) 221b, a memory device 221c and an I/O port 221d. The RAM 221b, the memory device 221c and the I/O port 221d are configured to be capable of exchanging data with the CPU 221a via an internal bus 221e. For example, a touch panel, a mouse, a keyboard, an operation terminal, or the like as an input/output device 225 may be connected to the controller 221. For example, a display, or the like as a display part may be connected to the controller 221.

The memory device 221c is composed of, for example, a flash memory, an HDD (Hard Disk Drive), a CD-ROM, or the like. The memory device 221c readably stores a control program for controlling the operation of the substrate processing apparatus 100, a process recipe describing procedures and conditions for substrate processing, and the like. The process recipe is a combination that causes the controller 221 composed of a computer to have the substrate processing apparatus 100 execute the respective procedures in a substrate processing process, which will be described later, to obtain a predetermined result. The process recipe functions as a program. Hereinafter, the process recipe, the control program, and the like are collectively and simply referred to as a program. In this specification, when the term “program” is used, it may include only the process recipe, only the control program, or both. The RAM 221b is configured as a memory area (work area) in which the programs and data read by the CPU 221a are temporarily stored.

The I/O port 221d is connected to the MFCs 252a to 252c, the valves 253a to 253c, 243a and 243b, the gate valve 244, the APC valve 242, the vacuum pump 246, the heater 217b, the RF sensor 272, the high-frequency power source 273, the frequency matcher 274, the susceptor elevating mechanism 268, the impedance changing mechanism 275, and the like.

The CPU 221a is configured to read the control program from the memory device 221c and execute the same, and is configured to read the process recipe from the memory device 221c in response to an input of an operation command from the input/output device 225 or the like. Then, as shown in FIG. 1, the CPU 221a is configured to, according to the contents of the process recipe thus read, control the operation of adjusting the opening degree of the APC valve 242, the opening/closing operation of the valve 243b and the start/stop of the vacuum pump 246 through the I/O port 221d and a signal line A, control the elevating operation of the susceptor elevating mechanism 268 through a signal line B, control the operation of adjusting the electric power supplied to the heater 217b based on the temperature sensor by the heater power adjustment mechanism 276 (temperature adjustment operation) and the impedance value adjustment operation by the impedance changing mechanism 275 through a signal line C, control the opening/closing operation of the gate valve 244 through a signal line D, control the operations of the RF sensor 272, the frequency matcher 274 and the high-frequency power source 273 through a signal line E, and control the flow rate adjustment operation for various gases by the MFCs 252a to 252c and the opening/closing operation of the valves 253a to 253c and 243a through a signal line F.

The controller 221 is not limited to being configured as a dedicated computer, and may be configured as a general-purpose computer. For example, the controller 221 according to the present embodiment may be configured by preparing an external memory device (e.g., a magnetic tape, a magnetic disk such as a flexible disk or a hard disk, an optical disk such as a CD or a DVD, a magneto-optical disk such as an MO or the like, or a semiconductor memory such as a USB memory or a memory card) 226 and installing a program in a general-purpose computer using such an external memory device 226. The means for supplying the program to the computer is not limited to supplying the program via the external memory device 226. For example, the program may be supplied using a communication means such as the Internet or a dedicated line without having to use the external memory device 226. The memory device 221c and the external memory device 226 are configured as computer-readable recording media. Hereinafter, these are collectively and simply referred to as recording medium. The term “recording medium” used in this specification may include only the memory device 221c, only the external memory device 226, or both.

### (2) Substrate Processing Process

As a process of manufacturing a semiconductor device using the substrate processing apparatus 100, an example of a substrate processing sequence for processing a wafer 200 as a substrate, specifically, a sequence example of forming an oxide layer by modifying the surface of a film formed on the surface of a wafer 200 will now be described. In the following description, the operation of each component of the substrate processing apparatus 100 is controlled by the controller 221.

The substrate processing sequence according to the present embodiments includes:

step a of modifying (oxidizing) a surface of a wafer 200 into a first oxide layer by supplying, to the wafer 200, a reactive species generated by plasma-exciting a first processing gas in which oxygen and hydrogen are contained and a ratio of hydrogen in the oxygen and hydrogen is a first ratio; and

step b of modifying the first oxide layer into a second oxide layer by supplying, to the wafer 200, a reactive species generated by plasma-exciting a second processing gas in which oxygen and hydrogen are contained and a ratio of hydrogen in the oxygen and hydrogen is a second ratio smaller than the first ratio.

As described below in the Modification 1 of the present disclosure, hydrogen contained in the second processing gas is optional. That is, the second processing gas may be free of hydrogen.

The term “wafer” used herein may refer to “a wafer itself” or “a stacked body of a wafer and a predetermined layer or film formed on the surface of the wafer.” The phrase “a surface of a wafer” used herein may refer to “a surface of a wafer itself” or “a surface of a predetermined layer or the like formed on a wafer.” The expression “a predetermined layer is formed on a wafer” used herein may mean that “a predetermined layer is directly formed on a surface of a wafer itself” or that “a predetermined layer is formed on a layer or the like formed on a wafer.” The term “substrate” used herein may be synonymous with the term “wafer.”

### (Wafer Loading)

In a state in which the susceptor 217 is lowered to a predetermined transfer position, the gate valve 244 is opened and the wafer 200 to be processed is transferred into the process chamber 201 by a transfer robot (not shown). The wafer 200 loaded into the process chamber 201 is horizontally supported on the support pins 266 protruding from the surface of the susceptor 217. After the loading of the wafer 200 into the process chamber 201 is completed, the arm of the transfer robot is withdrawn from the process chamber 201 and the gate valve 244 is closed. Thereafter, the susceptor 217 is raised to a predetermined processing position, and the wafer 200 to be processed is transferred from the support pins 266 onto the susceptor 217. The wafer may be loaded while purging the inside of the process chamber 201 with an inert gas or the like.

The surface of the wafer 200 to be modified is composed of, for example, a base of Si alone (monocrystalline Si, polycrystalline Si, or amorphous silicon). That is, the surface of the wafer 200 is composed of, for example, a base containing Si. As used herein, the term “base” includes, for example, a case where the base is in the form of a film, or a case where the base is an exposed surface of a wafer as a substrate.

### (Pressure Regulation and Temperature Adjustment)

Subsequently, the inside of the process chamber 201 is vacuum-exhausted by the vacuum pump 246 so as to have a desired processing pressure. The pressure inside the process chamber 201 is measured by a pressure sensor, and the APC valve 242 is feedback-controlled based on this measured pressure information. Further, the wafer 200 is heated by the heater 217b so as to reach a desired processing temperature. After the inside of the process chamber 201 reaches the desired processing pressure and the temperature of the wafer 200 reaches the desired processing temperature and becomes stable, a nitriding process, which will be described later, is started. The vacuum pump 246 is kept in operation until the wafer unloading, which will be described later, is completed.

Thereafter, the following steps a and b are executed sequentially.

### [Step a: First Oxide Layer Forming Step]

Step a includes:

step a-1 of supplying an oxygen-containing gas and a hydrogen-containing gas into the process chamber 201; and

step a-2 of modifying (oxidizing) the surface of the wafer 200 into the first oxide layer by plasma-exciting a gas which contains the oxygen-containing gas and the hydrogen-containing gas supplied into the process chamber 201, and supplying a reactive species generated by the plasma excitation to the wafer 200.

Specifically, the valve 253a is opened to allow the hydrogen-containing gas to flow into the gas supply pipe 232a, and the valve 253b is opened to allow the oxygen-containing gas to flow into the gas supply pipe 232b. The flow rates of the hydrogen-containing gas and the oxygen-containing gas are adjusted by the MFCs 252a and 252b. The hydrogen-containing gas and the oxygen-containing gas are supplied into the process chamber 201 through the buffer chamber 237, and are exhausted from the exhaust port 235. At this time, a mixed gas of the hydrogen-containing gas and then oxygen-containing gas is supplied into the process chamber 201 as a first processing gas containing hydrogen and oxygen (first processing gas supply). At this time, the valve 243c may be opened to simultaneously supply an inert gas into the process chamber 201 through the buffer chamber 237.

As the hydrogen-containing gas, for example, a hydrogen (H₂) gas, a deuterium (D₂) gas, a water vapor (H₂O gas), a hydrogen peroxide (H₂O₂) gas, or the like may be used. One or more of these gases may be used as the hydrogen-containing gas.

As the oxygen-containing gas, for example, an oxygen (O₂) gas, a nitrous oxide (N₂O) gas, a nitric oxide (NO) gas, a nitrogen dioxide (NO₂) gas, an ozone (O₃) gas, a water vapor (H₂O gas), a carbon monoxide (CO) gas, a carbon dioxide (CO₂) gas, or the like may be used. One or more of these gases may be used as the oxygen-containing gas. When a hydrogen-containing gas such as an H₂O gas or an H₂O₂ gas is used as the oxygen-containing gas, it is desirable that a gas other than these gases is used as the hydrogen-containing gas.

As the inert gas, for example, a N₂ gas, or a rare gas such as an argon (Ar) gas, a helium (He) gas, a neon (Ne) gas or a xenon (Xe) gas may be used. One or more of these gases may be used as the inert gas. This point also applies to each step described later.

At this time, as for ratios of hydrogen in the oxygen and hydrogen which are contained in the first processing gas, the flow rates of the hydrogen-containing gas and the oxygen-containing gas are adjusted by the MFCs 252a and 252b such that the ratio of hydrogen in the oxygen and hydrogen becomes a first ratio. In this way, by separately providing the hydrogen-containing gas supply system and the oxygen-containing gas supply system so as to individually adjust the flow rates, it becomes easy to adjust the mixing ratio of the hydrogen-containing gas and the oxygen-containing gas and to control the ratio of hydrogen in the processing gas.

In this specification, the expression “ratio of hydrogen in the oxygen and hydrogen” contained in the gas mainly refers to a ratio of the number of hydrogen atoms in the total number of oxygen atoms and hydrogen atoms contained in the gas. In this specification, the ratio of hydrogen in the oxygen and hydrogen is mainly expressed by a percentage of hydrogen in the oxygen and hydrogen, but the ratio may also be expressed by other form of ratio.

Simultaneously with or after starting the supply of the first processing gas, high-frequency (RF) power is applied from the high-frequency power source 273 to the resonance coil 212. As a result, an inductive plasma having a donut shape in a plan view is excited at the height positions corresponding to the upper and lower ground points and the electrical midpoint of the resonance coil 212 in the plasma generation space 201a. The excitation of the inductive plasma activates the first processing gas containing hydrogen and oxygen to generate a reactive species including an oxidation species. The reactive species includes at least one selected from the group of excited O atoms (O*) acting as oxidation species, ionized O atoms, excited OH groups (OH*), and ions containing O and H. Furthermore, the reactive species includes at least one selected from the group of excited H atoms (H*) and ionized H atoms as a reactive species containing H atoms. The reactive species containing H atoms may also be regarded as a part of the oxidation species.

As in the present embodiments, by plasma-exciting the processing gas supplied into the process chamber 201 to generate the reactive species and directly supplying the reactive species to the wafer 200, it is possible to efficiently supply the generated reactive species to the wafer 200 and improve the efficiency of oxidation and modification of the surface of the wafer 200 as compared with a case where the reactive species generated outside the process chamber 201 is supplied to the wafer 200.

An example of a processing condition in this step is described as follows.

Processing temperature: room temperature to 300 degrees C., specifically 100 to 200 degrees C.

Processing pressure: 1 to 1,000 Pa, specifically 100 to 200 Pa

Ratio of hydrogen in the oxygen and hydrogen in first processing gas: 60 to 95%, specifically 70 to 95%

First processing gas supply flow rate: 0.1 to 10 slm, specifically 0.2 to 0.5 slm

First processing gas supply time: 60 to 400 seconds, specifically 120 to 400 seconds

Inert gas supply flow rate: 0 to 10 slm

RF power: 100 to 5,000 W, specifically 500 to 3,500 W

RF frequency: 800 kHz to 50 MHz

As used herein, the expression of a numerical range such as “100 to 200 degrees C.” means that the lower limit and the upper limit are included in the range. Therefore, for example, “100 to 200 degrees C.” means “100 degrees C. or more and 200 degrees C. or less”. The same applies to other numerical ranges. Further, as used herein, the term processing temperature means the temperature of the wafer 200 or the temperature inside the process chamber 201, and the term processing pressure means the pressure inside the process chamber 201. In addition, gas supply flow rate 0 slm means a case where a gas is not supplied. These also apply to the following descriptions.

The reactive species including the oxidation species are supplied to the surface of the wafer 200 by plasma-exciting the first processing gas and supplying it to the wafer 200 under the above-described processing condition. The surface of the wafer 200 is oxidized by the supplied reactive species, and at least the surface of the wafer 200 is modified into a first oxide layer.

When the surface of a substrate is oxidized using a plasma-excited oxygen-containing gas at a relatively low processing temperature like the processing temperature exemplified in this step to form an oxide layer on the surface of the substrate, under the conventional condition, it may be impossible to obtain a desired oxidation rate, and it may be difficult to form an oxide layer with a desired thickness. Presumably, this is because under the low-temperature condition, the oxidation species generated by plasma excitation is less likely to diffuse into the modification target (e.g., Si base) on the surface of the substrate, and under the low-temperature condition, the oxidation species is less likely to be generated by plasma excitation (that is, the amount of oxidation species generated decreases).

In order to solve such problems, it is conceivable to increase the processing temperature to promote the diffusion of the oxidation species or promote the generation of the oxidation species. However, the increase of the processing temperature is often not desirable in light of the thermal history (thermal budget) for the device structure formed on the wafer 200. Therefore, there may be a case that requires a means for carrying out a modification process while maintaining the processing temperature at a relatively low temperature.

Therefore, in this step, by setting the first ratio, which is the ratio of hydrogen in the oxygen and hydrogen contained in the plasma-excited processing gas, to a predetermined ratio or more, it is possible to realize the improvement of the oxidation rate and/or the increase of the thickness of the oxide layer at a relatively low processing temperature.

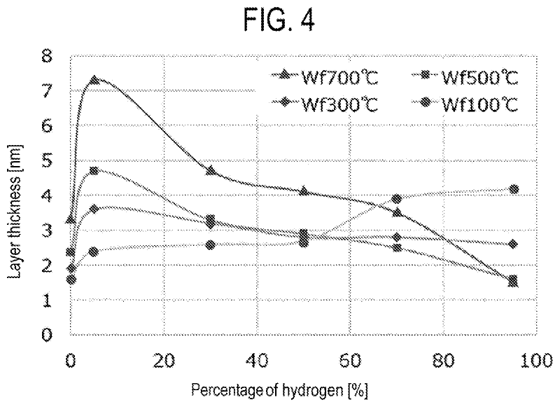

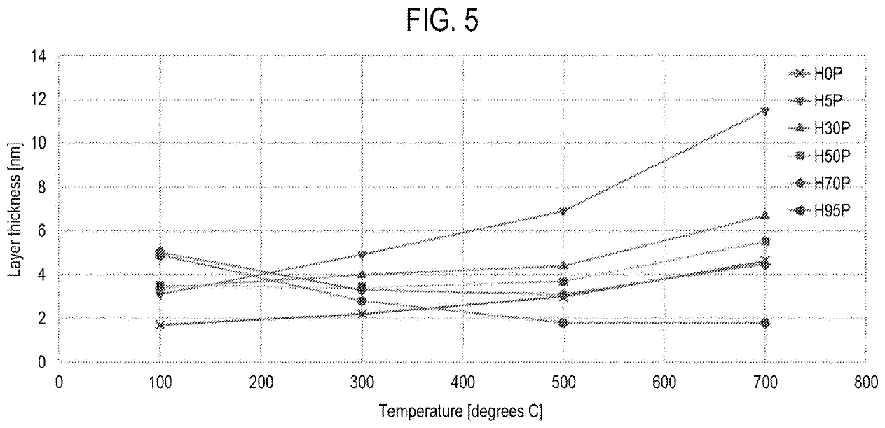

A more specific description will be given below with reference to FIGS. 4 and 5. FIG. 4 is a diagram showing the relationship between the ratio of hydrogen in the oxygen and hydrogen contained in the processing gas and the thickness of the oxide layer formed by the modification process when the processing temperature is set to 100 degrees C., 300 degrees C., 500 degrees C., and 700 degrees C. FIG. 5 is a diagram showing the relationship between the processing temperature and the thickness of the oxide layer formed by the modification process when the ratio of hydrogen in the oxygen and hydrogen contained in the processing gas is set to 0% (i.e., hydrogen-free), 5%, 30%, 50%, 70%, and 95%. The conditions for these modification processes are set to fall within the range of the condition described in step a, except for the processing temperature and the ratio of hydrogen in the oxygen and hydrogen contained in the processing gas. The modification process target is also the same (i.e., Si base).

As shown in FIG. 4, when the modification process is performed under the condition in which the processing temperature is a relatively low temperature such as 100 degrees C. or 300 degrees C., the thickness of the oxide layer formed by the modification process tends to increase in the region where a ratio of hydrogen in the processing gas is a high ratio of 60% or more and 95% or less, compared with that in the region where a ratio of hydrogen in the processing gas is lower than 60%. Further, as shown in FIG. 5, when the modification process is performed under the condition in which a ratio of hydrogen in the processing gas is a high ratio of 70% or 95%, the thickness of the oxide layer formed by the modification process tends to increase in the region where the processing temperature is 300 degrees C. or less, compared with that in the region where the processing temperature is higher than 300 degrees C.

As for reason why the oxidation rate or the thickness of the oxide layer is increased by increasing the ratio of hydrogen in the processing gas under the low temperature condition like above, there may be considered that H and/or H-containing reactive species in the processing gas promote (assist) the oxidation action of the oxidation species, and that under the low temperature condition, H and/or reactive species containing H, which are diffused into the modification process target (base, etc.), are less likely to be desorbed from the modification process target and is likely to remain in the modification process target.

Therefore, in this step, as the processing temperature, a temperature at which the oxidation rate (the formation rate of the oxide layer) on the surface of the wafer 200 increases when the ratio of hydrogen contained in the processing gas in this step is increased, or a temperature at which the thickness of the formed oxide layer increases is selected. By selecting such a processing temperature, it is possible to maintain or increase the oxidation rate or the thickness of the oxide layer even under the low temperature condition by increasing the ratio of hydrogen in the first processing gas.

Further, in this step, as the first ratio that is the ratio of hydrogen contained in the first processing gas, a ratio at which the oxidation rate of the surface of the wafer 200 decreases as the processing temperature increases in this step, or a ratio in which the thickness of the formed oxide layer decreases is selected. In other words, in this step, a ratio of hydrogen at which the oxidation rate of the surface of the wafer 200 increases as the processing temperature decreases in this step is selected as the first ratio. By selecting such a ratio of hydrogen, it is possible to maintain or increase the oxidation rate or the thickness of the oxide layer even under the low temperature conditions.

More specifically, in this step, the processing temperature is set to the room temperature or higher and 300 degrees C. or lower, specifically 100 degrees C. or higher and 200 degrees C. or lower, and the ratio of hydrogen in the oxygen and hydrogen in the first processing gas is set to 60% or higher and 95% or lower, specifically 70% or higher and 95% or lower.

By setting the processing temperature to 300 degrees C. or lower, the oxidation rate or the thickness of the oxide layer can be maintained even when this step is performed using the processing gas having a high ratio of hydrogen. When the processing temperature exceeds 300 degrees C., if this step is performed using the processing gas having a high ratio of hydrogen, the oxidation rate or the thickness of the oxide layer may not be maintained, and the influence of thermal history on the device structure on the wafer 200 may become conspicuous. Furthermore, by setting the processing temperature to 200 degrees C. or less, this step can be performed using the processing gas having a high ratio of hydrogen, and the oxidation rate or the thickness of the oxide layer can be improved. Furthermore, by setting the processing temperature to the room temperature or higher, a means for cooling the wafer 200 is not needed, and by setting the processing temperature to 100 degrees C. or higher, it is easy to stabilize the temperature of the wafer 200.

Further, by setting the ratio of hydrogen in the first processing gas to 60% or more and 95% or less, the oxidation rate or the thickness of the oxide layer can be maintained or improved even under the low temperature condition such as 300 degrees C. or less. If the ratio of hydrogen is less than 60%, it may be difficult to maintain the oxidation rate or the thickness of the oxidation layer under the low temperature condition. If the ratio of hydrogen exceeds 95%, an amount of oxidation species generated by plasma excitation may be significantly reduced, and it may become difficult to maintain a practical oxidation rate or thickness of the oxide layer.

The thickness of the oxide layer formed on the surface of the wafer 200 in this step is desirably 4 nm or more, more desirably 5 nm or more. By forming the oxide layer having a thickness of 4 nm or more, insulation can be secured even when the oxide layer is used as an insulating layer. Further, as shown in FIG. 5, for example, in a low-temperature region where the processing temperature is 200 degrees C. or less, when the ratio of hydrogen in the processing gas is less than 70%, it may be difficult to form an oxide layer having a thickness of 4 nm or more. Therefore, in order to form an oxide layer having a thickness of 4 nm or more in the low temperature region, it is desirable to perform the modification process under the processing condition of this step.

In this step, as H contained in the processing gas remains in the first oxide layer formed on the surface of the wafer 200, it may be considered that the properties of the oxide layer such as the processing resistance (wet etching resistance, dry etching resistance, etc.) of the first oxide layer, the electrical property, and the like deteriorate. Therefore, in the present embodiment, step b described later is further performed after this step (step a) to modify the first oxide layer so as to reduce the hydrogen concentration in the first oxide layer, thereby improving the properties thereof.

After the above-described modification process is completed, the valves 253a and 253b are closed to stop the supply of the hydrogen-containing gas and the oxygen-containing gas into the process chamber 201, and the supply of the RF power to the resonance coil 212 is stopped. Then, the inside of the process chamber 201 is vacuum-exhausted to remove the gases and the like remaining in the process chamber 201 from the inside of the process chamber 201. At this time, the valve 253 c is opened to supply the inert gas into the process chamber 201. The inert gas acts as a purge gas, thereby purging the inside of the process chamber 201 (purge).

In this embodiment, the above-described purge process is performed between the modification process of step a and step b. The purge step may not be performed. After the modification process of step a is completed, step b may be started while continuing to apply the RF power to the resonance coil 212. In such a case, the supply flow rate or the flow rate ratio of the hydrogen-containing gas and the oxygen-containing gas supplied into the process chamber 201 (i.e., the ratio of hydrogen in the processing gas) may be changed in a stepwise manner or may be changed gradually over a predetermined period of time.

### [Step b: Second Oxide Layer Forming Step]

Step b includes:

step b-1 of supplying the oxygen-containing gas and the hydrogen-containing gas into the process chamber 201; and

step b-2 of modifying the first oxide layer into a second oxide layer by plasma-exciting the gases containing the oxygen-containing gas and the hydrogen-containing gas supplied into the process chamber 201 and supplying a reactive species generated by the plasma excitation to the wafer 200.

Specifically, the valve 253a is opened to allow the hydrogen-containing gas to flow into the gas supply pipe 232a, and the valve 253b is opened to allow the oxygen-containing gas to flow into the gas supply pipe 232b. The flow rates of the hydrogen-containing gas and the oxygen-containing gas are adjusted by the MFCs 252a and 252b, respectively. The hydrogen-containing gas and the oxygen-containing gas are supplied into the process chamber 201 through the buffer chamber 237, and are exhausted from the exhaust port 235. At this time, a mixed gas of the hydrogen-containing gas and the oxygen-containing gas is supplied into the process chamber 201 as a second processing gas containing hydrogen and oxygen (second processing gas supply). Further, as in step a, the inert gas may be simultaneously supplied into the process chamber 201.

At this time, as for the ratios of hydrogen and oxygen contained in the second processing gas, the flow rates of the hydrogen-containing gas and the oxygen-containing gas are adjusted by the MFCs 252a and 252b such that the ratio of hydrogen in the oxygen and hydrogen becomes a second ratio smaller than the first ratio.

Simultaneously with or after starting the supply of the second processing gas, RF power is applied from the high-frequency power source 273 to the resonance coil 212. As a result, inductive plasma is excited in the plasma generation space 201a as in step a. The excitation of the inductive plasma activates the second processing gas containing hydrogen and oxygen to generate a reactive species containing an oxidation species as in step a. However, since the second processing gas, which has a ratio of hydrogen smaller than that of the first processing gas, is plasma-excited in this step, it may be considered that the ratio of hydrogen (atoms) contained in the generated reactive species becomes lower than that of the reactive species generated in step a.

An example of a processing condition in this step is described as follows.

Ratio of hydrogen in the oxygen and hydrogen in second processing gas: 0 to 20%, specifically 5 to 20%

Second processing gas supply flow rate: 0.1 to 10 slm, specifically 0.2 to 0.5 slm

Second processing gas supply time: 60 to 400 seconds, specifically 120 to 400 seconds

The processing temperature is substantially the same as or lower than that of step a. Particularly, in terms of omitting the time required to change the temperature between steps and in terms of promoting the modification effect on the first oxide layer, it is desirable that the processing temperature is set to be substantially equal to the processing temperature in step a rather than to be lower than the processing temperature in step a. The processing temperature may be set to be higher than the processing temperature in step a. In this case, the processing temperature is selected from a range below an allowable temperature in consideration of the influence of thermal history on the device structure on the wafer 200, and the like.

Further, the supply time of the second processing gas may be, for example, the same as the supply time of the first processing gas in step a. However, it is desirable to adjust the supply time of the second processing gas according to an allowable value of a concentration of hydrogen (atoms) remaining in the second oxide layer. For example, if the allowable concentration of hydrogen is high, the supply time is adjusted to be short. If the allowable concentration of hydrogen is low, the supply time is adjusted to be long. This makes it possible to improve the throughput.

Other processing condition is the same as the processing condition for supplying the nitrogen-containing gas in step a.

By plasma-exciting the second processing gas and supplying it to the wafer 200 under the above-described processing condition, a reactive species containing an oxidation species is supplied to the first oxide layer on the wafer 200. The supplied reactive species modifies the first oxide layer into a second oxide layer.

Specifically, in this step, the reactive species in which a ratio of hydrogen is smaller compared with the reactive species generated in step a, is supplied to the first oxide layer. As a result, while suppressing hydrogen from being introduced into the first oxide layer, the hydrogen (atoms) that has been introduced into the first oxide layer is desorbed from the first oxide layer by the oxidation species or the like, and the first oxide layer is modified into a second oxide layer in which the concentration of hydrogen is reduced. The second oxide layer formed by modification has improved properties such as a processing resistance (wet etching resistance, dry etching resistance, etc.), an electrical property and the like as compared to the first oxide layer. For example, the second oxide layer has a lower wet etching rate (WER (Å/min)) than that of the first oxide layer. For evaluation of the WER, for example, an etching rate when etching is performed using a hydrogen fluoride aqueous solution (DHF solution) diluted to 1% is used.

In this step, a ratio of hydrogen at which the oxidation rate of the surface of the wafer 200 increases as the processing temperature increases in the modification process of step a is desirably selected as the second ratio that is the ratio of hydrogen contained in the second processing gas. By selecting such a ratio of hydrogen, the hydrogen contained in the first oxide layer can be efficiently desorbed while maintaining the low temperature condition.

More specifically, in this step, the ratio of hydrogen to oxygen in the second processing gas is set to 0% or more and 20% or less, specifically 5% or more and 20% or less. By setting the ratio of hydrogen in the second processing gas to 0% or more and 20% or less, the hydrogen contained in the first oxide layer can be desorbed while maintaining the low temperature condition. If the ratio of hydrogen in the second processing gas exceeds 20%, it may become difficult to desorb the hydrogen contained in the first oxide layer. Furthermore, by setting the ratio of hydrogen in the second processing gas to 5% or more, the hydrogen contained in the first oxide layer can be efficiently desorbed while maintaining the low temperature condition. If the ratio of hydrogen in the second processing gas is less than 5%, especially a generated amount of OH radicals may be reduced, and the efficiency of desorbing the hydrogen contained in the first oxide layer may be reduced.

After the above-described modification process is completed, the valves 253a and 253b are closed to stop the supply of the hydrogen-containing gas and the oxygen-containing gas into the process chamber 201, and the supply of the RF power to the resonance coil 212 is stopped.

### (After-Purge and Atmospheric Pressure Restoration)

After step b is completed, the inside of the process chamber 201 is vacuum-exhausted, and the gas remaining in the process chamber 201 is removed from the inside of the process chamber 201. Then, gaseous substances and the like remaining in the process chamber 201 are removed from the process chamber 201 by the same processing procedure and processing condition as the purge described above (after-purge). Thereafter, the atmosphere in the process chamber 201 is replaced with the purge gas, and the pressure in the process chamber 201 is restored to the atmospheric pressure (atmospheric pressure restoration).

### (Wafer Unloading)

Subsequently, the susceptor 217 is lowered to the predetermined transfer position, and the wafer 200 is transferred from the susceptor 217 onto the support pins 266. Thereafter, the gate valve 244 is opened, and the processed wafer 200 is unloaded from the process chamber 201 using the transfer robot (not shown). Thus, the substrate processing process according to the present embodiments is finished.

### (3) Modification

The substrate processing sequence according to the present embodiments may be changed as in the modifications described below. These modifications may be combined arbitrarily. Unless otherwise specified, the processing procedure and processing condition in each step of each modification may be the same as the processing procedure and processing condition in each step of the substrate processing sequence described above.

### (Modification 1)

In this modification, in step b, the ratio of hydrogen contained in the second processing gas is set to 0%. That is, no hydrogen is contained. Specifically, in step b, the hydrogen-containing gas is not supplied from the hydrogen-containing gas supply system, and the oxygen-containing gas is merely supplied from the oxygen-containing gas supply system. In this case, as the oxygen-containing gas, a hydrogen-free gas such as an O₂ gas or an O₃ gas is used.

Also in this modification, the same effects as those of the above-described embodiments can be obtained. Further, according to this modification, the second processing gas in step b does not contain hydrogen. Therefore, substantially no additional hydrogen is introduced into the first oxide layer in step b. This can promote the desorption of hydrogen from the first oxide layer.

### (Modification 2)

In the above-described embodiments, there has been described the example where in step a, the mixed gas of the gases supplied from the hydrogen-containing gas supply system and the oxygen-containing gas supply system is supplied as the first processing gas into the process chamber 201, and similarly, in step b, the mixed gas of the gases supplied from the hydrogen-containing gas supply system and the oxygen-containing gas supply system is supplied as the second processing gas into the process chamber 201. On the other hand, the substrate processing apparatus according to this modification includes a first processing gas supply system that supplies a first processing gas in which a ratio of hydrogen contained therein is a first ratio, and a second processing gas supply system that supplies a second processing gas in which a ratio of hydrogen contained therein is a second ratio.

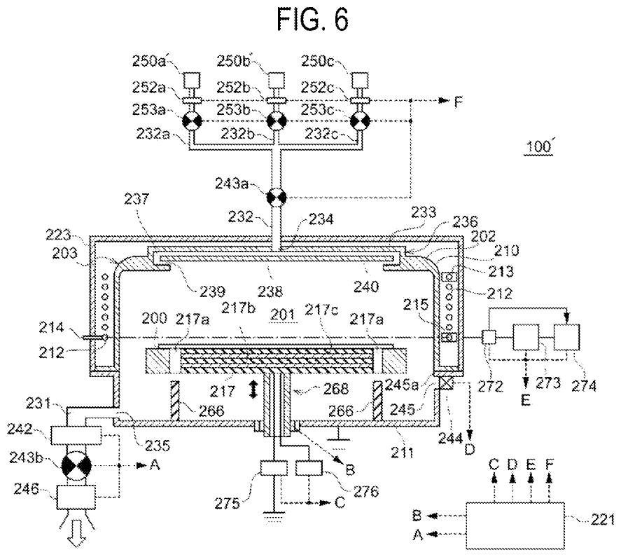

More specifically, for example, as in the configuration shown in FIG. 6, the substrate processing apparatus 100′ may include a first processing gas supply system including a first processing gas supply source 250a′ instead of the hydrogen-containing gas supply source 250a of the above-described embodiments, and a second processing gas supply system including a second processing gas supply source 250b′ instead of the oxygen-containing gas supply source 250b of the above-described embodiments. The controller 121 performs control so that in step a, the first processing gas is supplied into the process chamber 201 from the first processing gas supply system, and in step b, the second processing gas is supplied into the process chamber 201 from the second processing gas supply system.

Further, as in modification 1, the second processing gas supplied from the second processing gas supply system may be an oxygen-containing gas in which hydrogen is not contained.

### Other Embodiments of the Present Disclosure

The embodiments of the present disclosure have been specifically described above. However, the present disclosure is not limited to the embodiments described above, and various modifications may be made without departing from the scope of the present disclosure.

In the above-described embodiments, there has been described the example where the base made of Si alone is used as the modification process target. However, the present disclosure is not limited thereto. The modification process target may be made of, for example, Si-containing substances (Si compounds) such as silicon nitride (SiN), silicon oxynitride (SiON), silicon oxycarbonitride (SiOCN), silicon germanium (SiGe), and silicon carbide (SiC). Further, the modification process target may be made of, for example, a metal which contains aluminum (Al), tungsten (W), molybdenum (Mo), titanium (Ti), hafnium (Hf), or zirconium (Zr), or a compound thereof. However, the modification process target is desirably other than the oxides thereof.

In the above-described embodiments, there has been described the example where step a and step b are continuously performed in a single process chamber (i.e., the process chamber 201). However, the present disclosure is not limited thereto. For example, after performing step a on the substrate, the substrate may be transferred from the process chamber in which the processing has been performed, to a transfer chamber which is not opened to the atmosphere. Thereafter, the substrate may be loaded into another process chamber, and step b may be performed therein.

In the above-described embodiments, there has been described the example where the substrate processing process is performed using the single-substrate type substrate processing apparatus that processes one or more substrates at a time. The present disclosure is not limited to the embodiments described above, and may be suitably applied to a case of using a batch-type substrate processing apparatus that processes a plurality of substrates at a time.

Even when these substrate processing apparatuses are used, each process can be performed under the same processing procedures and processing conditions as those of the above-described embodiments and modifications, and the same effects as those of the above-described embodiments can be obtained.

According to the present disclosure in some embodiments, it is possible to modify the surface of a substrate into an oxide layer having a desired thickness and excellent properties even under low temperature conditions.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) modifying a surface of the substrate into a first oxide layer by supplying, to the substrate, a reactive species generated by plasma-exciting a first processing gas in which oxygen and hydrogen are contained and a ratio of hydrogen in the oxygen and hydrogen of the first processing gas is a first ratio; and
(b) modifying the first oxide layer into a second oxide layer by supplying, to the substrate, a reactive species generated by plasma-exciting a second processing gas in which oxygen is contained and hydrogen is optionally contained and a ratio of hydrogen in the oxygen and hydrogen of the second processing gas is a second ratio smaller than the first ratio.

2. The method of claim 1, wherein the substrate has a same predetermined temperature in (a) and (b).

3. The method of claim 2, wherein a temperature at which an oxidation rate of the surface of the substrate increases as a ratio of hydrogen in the oxygen and hydrogen of the first processing gas increases is selected as the predetermined temperature in (a).

4. The method of claim 2, wherein the predetermined temperature is 300 degrees C. or lower.

5. The method of claim 1, wherein a ratio of hydrogen in the oxygen and hydrogen of the first processing gas, at which an oxidation rate of the surface of the substrate increases as a temperature of the substrate decreases, is selected as the first ratio in (a).

6. The method of claim 1, wherein the first ratio is 60% or more and 95% or less.

7. The method of claim 1, wherein the second ratio is 20% or less.

8. The method of claim 7, wherein the second ratio is 5% or more.

9. The method of claim 1, wherein the second processing gas is a hydrogen-free gas.

10. The method of claim 1, wherein the surface of the substrate to be modified into the first oxide layer in (a) is composed of a base containing silicon.

11. The method of claim 10, wherein the base containing silicon is composed of silicon alone.

12. The method of claim 1, wherein a thickness of the first oxide layer is 4 nm or more.

13. The method of claim 1, wherein a concentration of hydrogen contained in the second oxide layer is lower than a concentration of hydrogen contained in the first oxide layer.

14. The method of claim 1, wherein in (a), the first processing gas supplied into a process chamber in which the substrate is accommodated is plasma-excited, and
wherein in (b), the second processing gas supplied into the process chamber is plasma-excited.

15. The method of claim 1, wherein the first processing gas is a mixed gas of an oxygen gas and a hydrogen gas.

16. A method of manufacturing a semiconductor device, comprising the method claim 1.

17. A substrate processing apparatus, comprising:
a process chamber in which a substrate is accommodated;
an oxygen-containing gas supply system configured to supply an oxygen-containing gas into the process chamber;
a hydrogen-containing gas supply system configured to supply a hydrogen-containing gas into the process chamber;
a plasma generator configured to plasma-excite a gas supplied into the process chamber; and
a controller configured to be capable of controlling the oxygen-containing gas supply system, the hydrogen-containing gas supply system, and the plasma generator so as to perform:
(a-1) supplying, into the process chamber, a first processing gas which contains the oxygen-containing gas and the hydrogen-containing gas and in which a ratio of hydrogen in oxygen and hydrogen contained in the first processing gas is a first ratio;
(a-2) modifying a surface of the substrate into a first oxide layer by supplying a reactive species generated by plasma-exciting the first processing gas to the substrate accommodated in the process chamber;
(b-1) supplying, into the process chamber, a second processing gas which contains the oxygen-containing gas and optionally contains the hydrogen-containing gas and in which a ratio of hydrogen in oxygen and hydrogen contained in the second processing gas is a second ratio smaller than the first ratio; and
(b-2) modifying the first oxide layer into a second oxide layer by supplying a reactive species generated by plasma-exciting the second processing gas to the substrate.

18. A non-transitory computer-readable recording medium storing a program that causes, by a computer, a substrate processing apparatus to perform a process comprising:
(a) modifying a surface of a substrate accommodated in a process chamber of the substrate processing apparatus into a first oxide layer by supplying, to the substrate, a reactive species generated by plasma-exciting a first processing gas in which oxygen and hydrogen are contained and a ratio of hydrogen in the oxygen and hydrogen of the first processing gas is a first ratio; and
(b) modifying the first oxide layer into a second oxide layer by supplying, to the substrate, a reactive species generated by plasma-exciting a second processing gas in which oxygen is contained and hydrogen is optionally contained and a ratio of hydrogen in the oxygen and hydrogen of the second processing gas is a second ratio smaller than the first ratio.
